(19) United States
(12) Patent Application Publication
(10) Pub. No.: US 2024/0038541 A1
(43) Pub. Date: Feb. 1, 2024

(54) METHODS FOR REMOVING MOLYBDENUM OXIDES FROM SUBSTRATES

(71) Applicant: Applied Materials, Inc., Santa Clara, CA (US)

(72) Inventors: Jiajie CEN, San Jose, CA (US); Xiaodong WANG, San Jose, CA (US); Kevin KASHEFI, San Ramon, CA (US); Shi YOU, San Jose, CA (US)

(21) Appl. No.: 17/961,153

(22) Filed: Oct. 6, 2022

Related U.S. Application Data
(60) Provisional application No. 63/392,655, filed on Jul. 27, 2022.

(51) Int. Cl. H01L 21/3065

(52) U.S. Cl. CPC H01L 21/3065

(57) ABSTRACT

Methods for cleaning oxides from a substrate surface are performed without affecting low-k dielectric or carbon materials on the substrate. In some embodiments, the method may include performing a preclean process with a chlorine-based soak to remove oxides from a surface of a substrate in a back end of the line (BEOL) process and treating the surface of the substrate with a remote plasma with a hydrogen gas and at least one inert gas to remove residual chlorine residue from the surface of the substrate without damaging low-k dielectric material or carbon material on the substrate.

### CROSS-REFERENCE TO RELATED APPLICATIONS

This application claims benefit of U.S. provisional patent application Ser. No. 63/392,655, filed Jul. 27, 2022, which is herein incorporated by reference.

### FIELD

Embodiments of the present principles generally relate to semiconductor chambers used in semiconductor processes.

### BACKGROUND

Molybdenum (Mo) surfaces when exposed to oxygen form a layer of molybdenum oxide (MoOₓ). The inventors have observed that removal of the MoOₓ requires harsh processes that are not compatible with back-end-of-the-line (BEOL) packaging processes. During BEOL processes, the MoOₓ may form in areas of low-k dielectric materials that are highly susceptible to damage caused by traditional precleaning processes.

Thus, the inventors have provided improved methods to remove molybdenum oxides from low-k dielectric materials in BEOL packaging processes without damaging the low-k dielectric materials.

### SUMMARY

Methods for a chlorine-based soak and diluted plasma preclean for molybdenum oxide are provided herein.

In some embodiments, a method for cleaning a surface of a substrate may comprise performing a chlorine-based soak process to remove molybdenum oxide from the surface of the substrate in a back-end-of-the-line (BEOL) process where the substrate contains, at least in part, low-k dielectric material and performing a plasma treatment on the surface of the substrate with a remote plasma containing a hydrogen gas diluted with at least one inert gas to remove residual chlorine residue from the surface of the substrate.

In some embodiments, the method may further include wherein the chlorine-based soak process uses molybdenum pentachloride (MoCl₅) or tungsten pentachloride (WCl₅), performing the chlorine-based soak process at a temperature of approximately 350 degrees Celsius to approximately 460 degrees Celsius, performing the chlorine-based soak process at a pressure of approximately 2 Torr to approximately 20 Torr, performing the chlorine-based soak process with a chlorine-based gas flowing at a rate of approximately 10 sccm to approximately 1000 sccm, performing the chlorine-based soak process for a duration of approximately 5 seconds to approximately 60 seconds, wherein the at least one inert gas is argon gas or helium gas, performing the plasma treatment at a temperature of approximately 250 degrees Celsius to approximately 460 degrees Celsius, performing the plasma treatment at a pressure of approximately 10 mTorr to approximately 200 mTorr, performing the plasma treatment with a plasma source power of approximately 400 watts to approximately 900 watts, performing the plasma treatment with a bias power of zero watts to approximately 300 watts, performing the plasma treatment with the hydrogen gas diluted down approximately 1% to approximately 99% by volume with the at least one inert gas, and/or performing the plasma treatment with the hydrogen gas flowing at a rate of approximately 1 sccm to approximately 100 sccm and the at least one inert gas flowing at a rate of approximately 5 sccm to approximately 200 sccm.

In some embodiments, a method for cleaning a surface of a substrate may comprise performing a chlorine-based soak process using molybdenum pentachloride (MoCl₅) or tungsten pentachloride (WCl₅) to remove molybdenum oxide from the surface of the substrate in a back-end-of-the-line (BEOL) process at a temperature of approximately 350 degrees Celsius to approximately 460 degrees Celsius for a duration of approximately 5 seconds to approximately 60 seconds where the substrate contains, at least in part, low-k dielectric material and performing a plasma treatment on the surface of the substrate with a remote plasma containing a hydrogen gas diluted with argon gas and helium gas at a temperature of approximately 250 degrees Celsius to approximately 460 degrees Celsius to remove residual chlorine residue from the surface of the substrate, wherein the hydrogen gas is diluted down approximately 3% to approximately 10% by volume with an argon gas and a helium gas.

In some embodiments, a non-transitory, computer readable medium having instructions stored thereon that, when executed, cause a method for cleaning a surface of a substrate to be performed, the method may comprise performing a chlorine-based soak process using molybdenum pentachloride (MoCl₅) or tungsten pentachloride (WCl₅) to remove molybdenum oxide from the surface of the substrate in a back-end-of-the-line (BEOL) process at a temperature of approximately 350 degrees Celsius to approximately 460 degrees Celsius for a duration of approximately 5 seconds to approximately 60 seconds, wherein the substrate contains, at least in part, low-k dielectric material and performing a plasma treatment on the surface of the substrate with a remote plasma containing a hydrogen gas diluted with argon gas and helium gas at a temperature of approximately 250 degrees Celsius to approximately 460 degrees Celsius to remove residual chlorine residue from the surface of the substrate, wherein the hydrogen gas is diluted down approximately 3% to approximately 10% by volume with an argon gas and a helium gas.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for reducing molybdenum oxides from low-k dielectric materials in accordance with some embodiments of the present principles.

FIG. 2 depicts a cross-sectional view of a substrate subjected to a chlorine-based soak in accordance with some embodiments.

FIG. 3 depicts a graph of chlorine-based soak effects on molybdenum oxides and molybdenum in accordance with some embodiments of the present principles.

FIG. 4 depicts a cross-sectional view of a substrate with chlorine residue after exposure to a chlorine-based soak in accordance with some embodiments.

FIG. 5 depicts a cross-sectional view of a substrate subjected to a remote plasma treatment with diluted hydrogen gas in accordance with some embodiments.

FIG. 6 depicts a cross-sectional view of a chlorine-based soaking chamber in accordance with some embodiments of the present principles.

FIG. 7 depicts a cross-section view of a remote plasma chamber in accordance with some embodiments of the present principles.

FIG. 8 depicts an integrated tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide an improved process for removing molybdenum oxide (MoOₓ) in back-end-of-the-line (BEOL) processes. Current BEOL preclean processes are challenged to reduce or remove molybdenum oxide without damage to low-k materials. The methods have the advantage over traditional BEOL preclean processes in that the methods can achieve full removal of MoOₓ with no chlorine residue in the low-k material and no significant carbon loss or damage to the low-k material. The methods are also compatible with current BEOL hydrogen gas (H₂) preclean approaches and integration flows.

While molybdenum materials/doping have been used in front-end-of-the-line (FEOL) structure manufacturing processes, molybdenum materials/doping have not been used in BEOL processes due to the inability to remove MoOₓ in areas containing low-k materials. Molybdenum materials/doping would allow for the formation of enhanced performance contacts formed during middle-of-the-line (MOL) processes such as in logic applications. If oxides formed on the exposed molybdenum materials can be removed during BEOL packaging processes, such MOL contacts become possible. Current processes lack any feasible approaches to reduce or remove the MoOₓ for BEOL without dealing significant damage to the low-k dielectric materials. For example, strong plasma treatments could fully reduce MoOₓ but would inevitably cause unacceptable damage to the low-k dielectric material—so such an approach cannot be applied to BEOL applications. Whereas the present principles provide a method to remove MoOₓ with negligible damage to the low-k dielectric materials. In some embodiments, a chlorine-based soak preclean process (e.g., molybdenum pentachloride (MoCl₅) or tungsten pentachloride (WCl₅) based soaking process, etc.) is used to remove the MoOₓ at a process temperature of approximately 400 degrees Celsius. A plasma-based treatment can then be used with hydrogen (H₂) gas diluted by an inert gas such as, but not limited to, argon and/or helium and the like to remove possible surface chlorine residue and/or dry etch residue and the like without damaging the low-k materials.

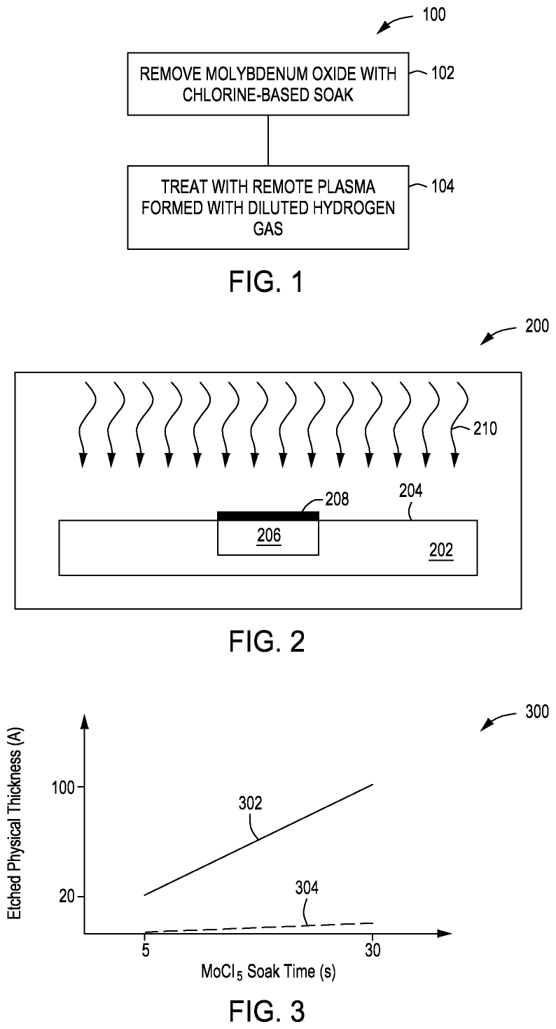

FIG. 1 is a method 100 for reducing molybdenum oxides from low-k dielectric materials in accordance with some embodiments. As used herein, ‘low-k’ refers to materials with a smaller dielectric constant or ‘k’ relative to silicon dioxide (i.e., low-k dielectric material has a ‘k’ value of less than 3.9). The method 100 is fully compatible with BEOL processes and may also be used in other processes. In block 102, a surface 204 of a substrate 202 containing a MoOₓ layer 208 on a molybdenum material 206 in a BEOL process is cleaned to reduce/remove the MoOₓ layer 208 using a chlorine-based soak 210 as depicted in a view 200 of FIG. 2. In some embodiments, the molybdenum material 206 may be a molybdenum doped material. In some embodiments, the chlorine-based soak 210 may be a MoCl₅ or WCl₅ based soak. In some embodiments, the chlorine-based soak 210 may be performed at a temperature of approximately 350 degrees Celsius to approximately 450 degrees Celsius. In some embodiments, the chlorine-based soak 210 may performed at a temperature of approximately 400 degrees Celsius. In some embodiments, the chlorine-based soak 210 may be performed at a pressure of approximately 2 Torr to approximately 20 Torr. In some embodiments, the chlorine-based soak 210 may be performed with a chlorine-based gas flow rate of approximately 10 sccm to approximately 1000 sccm. In some embodiments, the chlorine-based soak 210 may have a duration of approximately 5 seconds to approximately 60 seconds.

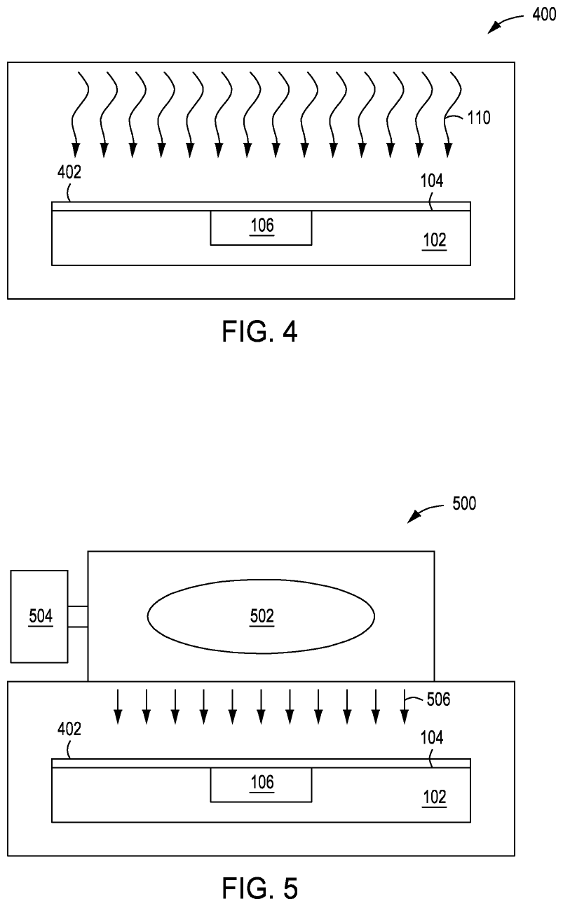

In some embodiments, as depicted in a graph 300, for example, the process temperature may be at approximately 425 degrees Celsius with a MoCl₅ gas flow at approximately 700 sccm, a pressure of approximately 10 Torr, and a duration of approximately 5 seconds to approximately 30 seconds. The MoOₓ etch rate 302 of the MoCl₅ soak process was approximately 4 angstroms/second while the molybdenum etch rate 304 was negligible (e.g., less than 0.01 angstroms/second, etc.). The chlorine-based soak 210 effectively reduces and/or removes the MoOₓ layer 208. The duration of the chlorine-based soak 210 may be adjusted based upon a thickness of the MoOₓ buildup and/or the type of structure on which the MoOₓ is found (e.g., high aspect ratio structures and the like may require a longer soak, etc.). While the MoOₓ layer 208 has been reduced/removed, the chlorine-based soak 210 has caused chlorine residue 402 to form on the surface 204 of the substrate 202 as depicted in a view 400 of FIG. 4.

In block 104 of the method 100 of FIG. 1, the surface 204 of the substrate in the BEOL process is exposed to a plasma treatment 506 with a remote plasma 502 formed with a diluted hydrogen gas 504 as depicted in a view 500 of FIG. 5. The plasma treatment 506 functions to remove any residual chlorine and/or dry etching residues from the surface 204 of the substrate 112 after the chlorine-based soak 210. In some embodiments, the diluted hydrogen gas 504 is diluted with an inert gas such as, but not limited to, argon and/or helium and the like. As the substrate 202 may contain low-k materials, using undiluted hydrogen gas with plasma produces a strong plasma that causes the hydrogen to recombine not only with the chlorine atoms but also with the carbon atoms in the low-k materials, damaging the low-k materials through carbon loss. The inventors discovered that by diluting the hydrogen gas down by approximately 1 percent to approximately 99 percent, by volume, with argon gas and/or helium gas, the carbon loss from the low-k materials of the substrate 202 was minimized while effectively reducing and/or removing the chlorine residue 402 on the surface 204 of the substrate 202. In some embodiments, the hydrogen gas is diluted down approximately 3 percent to approximately 10 percent, by volume, with argon gas and/or helium gas and the like to optimize chlorine removal while minimizing low-k damage. After further testing, the inventors found that the chlorine diffusion and carbon depletion are in the noise levels on both pristine and ash low-k materials (less than 1% below chlorine detection levels and less than 1% carbon loss in low-k materials). The inventors also found that the time-dependent dielectric breakdown (TDDB) after the method 100 was performed yielded similar results (e.g., greater than 10 years) as other BEOL cleaning processes (carbon loss in the low-k material was negligible and does not negatively affect the TDDB).

In some embodiments, the plasma treatment 506 is performed on the substrate 202 at a temperature of approximately 250 degrees Celsius to approximately 460 degrees Celsius. In some embodiments, the plasma treatment 506 is performed on the substrate 202 at a temperature of approximately 350 degrees Celsius. The inventors have found that lower pressures during the plasma treatment 506 yield better results (chlorine removal with minimal damage to low-k materials, etc.). In some embodiments, the plasma treatment 506 is performed at a pressure of approximately 10 mTorr to approximately 200 mTorr. In some embodiments, the plasma treatment 506 is performed at a pressure of approximately 10 mTorr to approximately 50 mTorr. In some embodiments, the plasma treatment 506 is performed with a plasma power level of approximately 400 watts to approximately 900 watts. In some embodiments, no bias power is applied to the substrate 202 during the plasma treatment 506. In some embodiments, greater than zero watts to approximately 300 watts of bias power is used during the plasma treatment 506. In some embodiments, greater than zero watts to approximately 100 watts of bias power is used during the plasma treatment 506. In some embodiments, H₂ gas is flowed at a rate of approximately 1 sccm to approximately 200 sccm during the plasma treatment 506. In some embodiments, H₂ gas is flowed at a rate of approximately 3 sccm to approximately 10 sccm during the plasma treatment 506. In some embodiments, argon gas is flowed at a rate of approximately 5 sccm to approximately 200 sccm during the plasma treatment 506. In some embodiments, argon gas is flowed at a rate of approximately 50 sccm to approximately 200 sccm during the plasma treatment 506. In some embodiments, helium gas is flowed at a rate of approximately 5 sccm to approximately 200 sccm during the plasma treatment 506. In some embodiments, helium gas is flowed at a rate of approximately 50 sccm to approximately 200 sccm during the plasma treatment 506. In some embodiments, the duration of the plasma treatment 506 may be from approximately 10 seconds to approximately 60 seconds.

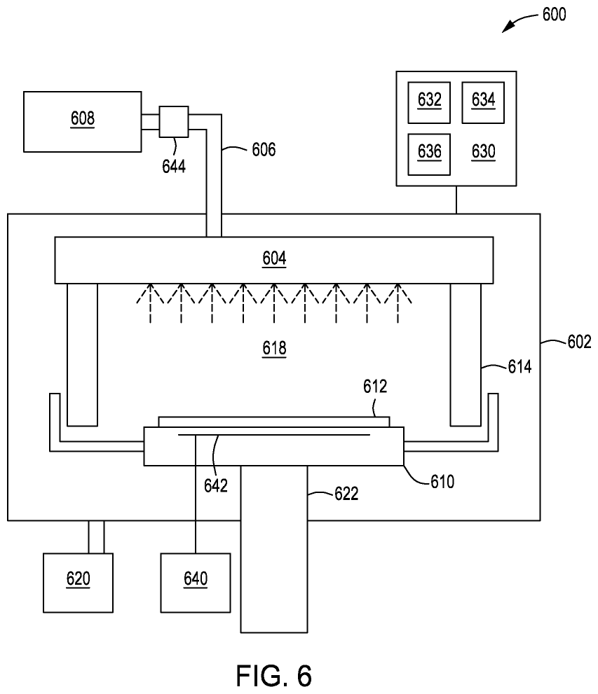

The chlorine-based soak process disclosed herein may be used in any chamber that provides chlorine-based gases for soaking along with temperature and pressure control. An example soaking chamber for performing the chlorine-based soak 210 is depicted in a view 600 of FIG. 6. The soaking chamber 602 includes a substrate support 622 that supports a substrate holder 610 and a shield 614 that surrounds a processing volume 618. A showerhead 604 provides a process gas or gases (e.g., chlorine-based gas such as, but not limited to, WCl₅, MoCl₅, etc.) into the processing volume 618 via a gas supply conduit 606 from a gas supply 608. The process gas flow rate is controlled by a gas flow valve 644. In some embodiments, the process gas may be supplied at a flow rate of approximately 10 sccm to approximately 1000 sccm. Contaminants or unwanted gases are removed from the soaking chamber 602 by a pump 620. The pump 620 may also be used to maintain the process pressure within the soaking chamber 602. In some embodiments, the process pressure may be from approximately 2 Torr to approximately 20 Torr. The soaking chamber 602 may also have thermal control elements or channels 642 that allow temperature control of the substrate 612 during processing by a temperature controller 640. In some embodiments, the process temperature may be approximately 350 degrees Celsius to approximately 460 degrees Celsius.

A controller 630 controls the operation of the soaking chamber 602 using a direct control of the soaking chamber 602 or alternatively, by controlling the computers (or controllers) associated with the soaking chamber 602. In operation, the controller 630 enables data collection and feedback from the respective systems to optimize performance of the soaking chamber 602. The controller 630 generally includes a Central Processing Unit (CPU) 632, a memory 634, and a support circuit 636. The CPU 632 may be any form of a general-purpose computer processor that can be used in an industrial setting. The support circuit 636 is conventionally coupled to the CPU 632 and may comprise a cache, clock circuits, input/output subsystems, power supplies, and the like. Software routines, such as a method as described herein may be stored in the memory 634 and, when executed by the CPU 632, transform the CPU 632 into a specific purpose computer (controller 630). The software routines may also be stored and/or executed by a second controller (not shown) that is located remotely from the soaking chamber 602. In some embodiments, the use of plasma may be included to facilitate in exposing the substrate to an oxygen rich environment during an optional oxygen-based treatment. The optional oxygen-based treatment may also assist in higher rate gap filling and affords another knob for tuning feature-to-feature gap fill height variations along with temperature, pressure, flow rates, and gas combinations.

The memory 634 is in the form of computer-readable storage media that contains instructions, when executed by the CPU 632, to facilitate the operation of the semiconductor processes and equipment. The instructions in the memory 634 are in the form of a program product such as a program that implements the methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

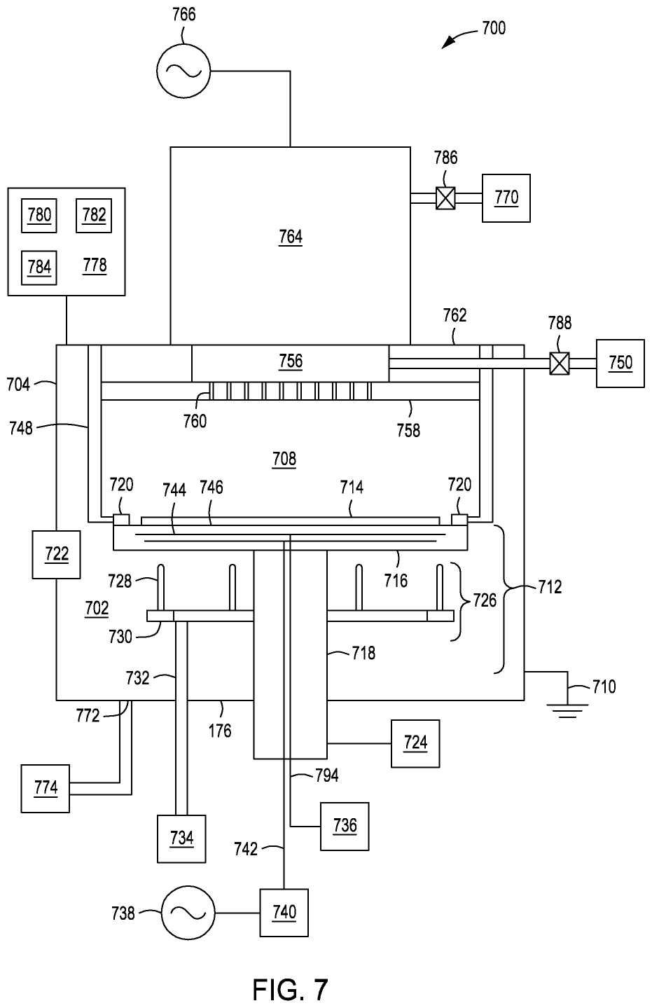

As an example chamber for performing a plasma treatment 506, FIG. 7 depicts a process chamber 700 with a remote plasma source 764 in accordance with some embodiments. The process chamber 700 is a vacuum chamber which is adapted to maintain sub-atmospheric pressures within an interior volume 702 during substrate processing. In some embodiments, the process chamber 700 can maintain a pressure of approximately 10 mTorr to approximately 200 mTorr. The process chamber 700 includes a chamber body 706 which encloses a processing volume 708 located in the upper half of the interior volume 702. The chamber body 704 may be made of metal, such as aluminum and the like. The chamber body 704 may be grounded via a coupling to ground 710.

A substrate support 712 is disposed within the interior volume 702 to support and retain a substrate 714, such as a semiconductor wafer, for example, or other such substrate. The substrate support 712 may generally comprise a pedestal 716 and a hollow support shaft 718 for supporting the pedestal 716. The pedestal 716 may be composed of an aluminum-based material or a ceramic-based material and the like. A pedestal formed of a ceramic-based material may be used for high temperature processes. The hollow support shaft 718 provides a conduit to provide, for example, backside gases, process gases, fluids, coolants, power, or the like, to the pedestal 716. In some embodiments, the substrate support 712 includes a focus ring 720 disposed about the pedestal 716 to enhance process uniformity at an edge of the substrate 714. In some embodiments, the focus ring 720 is made of quartz-based materials. In some embodiments, the focus ring 720 is made of ceramic-based materials. The ceramic-based material facilitates high pressure process capabilities. A slit valve 722 may be coupled to the chamber body 704 to facilitate in transferring the substrate 714 into and out of the interior volume 702.

In some embodiments, the hollow support shaft 718 is coupled to a lift actuator 724, such as a motor, which provides vertical movement of the pedestal 716 between an upper, processing position, and a lower, transfer position. A substrate lift 726 can include lift pins 728 mounted on a platform 730 connected to a shaft 732 which is coupled to a second lift actuator 734 for raising and lowering the substrate lift 726 so that the substrate 714 may be placed on or removed from the pedestal 716. The pedestal 716 may include through-holes to receive the lift pins 728. The hollow support shaft 718 provides a path for a gas conduit 794 for coupling a backside gas supply 736 and/or an RF power supply 738 to the pedestal 716. In some embodiments, the RF power supply 738 provides bias power through a matching network 740 to a power conduit 742 to the pedestal 716. In some embodiments, RF energy supplied by the RF power supply 738 may have a frequency of about 2 MHz or greater. In some embodiments, the RF power supply 738 may have a frequency of about 13.56 MHz.

In some embodiments, the backside gas supply 736 is disposed outside of the chamber body 704 and supplies gas to the pedestal 716. In some embodiments, the pedestal 716 includes a gas channel 744, allowing gas to interact with a backside of the substrate 714 to maintain a given temperature. The gas channel 744 is configured to provide backside gas, such as nitrogen (N₂), argon (Ar), or helium (He), to an upper surface 746 of the pedestal 716 to act as a heat transfer medium. The gas channel 744 is in fluid communication with the backside gas supply 736 via gas conduit 794 to control the temperature and/or temperature profile of the substrate 714 during use. For example, the backside gas supply 736 can supply gas to cool and/or heat the substrate 714 during use. In some embodiments, the substrate 714 may be heated from approximately 275 degrees Celsius to approximately 420 degrees Celsius.

The process chamber 700 includes a process kit circumscribing various chamber components to prevent unwanted reaction between such components and contaminants. The process kit includes an upper shield 748. In some embodiments, the upper shield 748 may be made of metal, such as aluminum. In some embodiments, the process kit may be constructed of quartz. In some embodiments, a mixing reservoir 756 is coupled to and in fluid communication with the processing volume 708. The mixing reservoir 756 is also fluidly connected to the RPS 764. The mixing reservoir 756 allows mixing of the plasma gases with other gases provided by a gas delivery system 750. The gas delivery system 750 may include an ampoule that is used to supply a gas, such as a chlorine-based gas, and the like to the process volume 708. A rate of flow of the other gases from the gas delivery system 750 may be controlled by a first flow valve 788.

A showerhead 758 is located above the processing volume 708 and below a ceiling 762 of the chamber body 704. The showerhead 758 includes through-holes 760 to flow gases from the mixing reservoir 756 into the processing volume 708. The RPS 764 is fluidly connected to the mixing reservoir 756 to allow ionized gases to flow from the RPS 764 into the mixing reservoir 756, through the showerhead 758, and into the processing volume 708. Plasma is generated in the RPS 764 by a plasma RF power source 766 that provides RF energy to the RPS 764. Process gases used to form the plasma are supplied by a process gas source 770 and controlled by a second flow valve 786. The plasma gases supplied by the process gas source 770 may include, but are not limited to, hydrogen, helium, and/or argon and the like. The second flow valve 786 may contain one or more flow valves to control the amount and flow rate of the gases into the RPS 764. A controller 778 may be used to achieve desired flow rates for individual gases and the desired hydrogen dilution as described in the above method 100. The RPS 764 produces ions and radicals of the process gas to facilitate in processing the substrate 714. In some embodiments, plasma is directly generated within the processing volume 708 and used with, for example, diluted hydrogen gas with one or more inert gases to facilitate in removing any chlorine and/or etch-based residues after soaking of a substrate surface according to the methods of the present principles.

A pump port 772 is configured to facilitate removal of particles and gases from the interior volume 702. The process chamber 700 is coupled to and in fluid communication with a vacuum system 774 which includes a throttle valve (not shown) and pump (not shown) which are used to exhaust the process chamber 700. In some embodiments, the vacuum system 774 is coupled to the pump port 772 disposed on a bottom surface 776 of the chamber body 704. The pressure inside the process chamber 700 may be regulated by adjusting the throttle valve and/or vacuum pump. In some embodiments, the pump has a flow rate of approximately 1900 liters per second to approximately 3000 liters per second. In some embodiments, the vacuum system 774 may be used to facilitate in regulating the substrate temperature.

In some embodiments, the controller 778 is used for the operation of the process chamber 700. The controller 778 may use direct control of the process chamber 700 or alternatively, use indirect control of the process chamber 700 by controlling computers (or controllers) associated with the process chamber 700. In operation, the controller 778 enables data collection and feedback from the process chamber 700 to optimize performance of the process chamber 700. The controller 778 generally includes a Central Processing Unit (CPU) 780, a memory 782, and a support circuit 784. The CPU 780 may be any form of a general-purpose computer processor that can be used in an industrial setting. The support circuit 784 is conventionally coupled to the CPU 780 and may comprise a cache, clock circuits, input/output subsystems, power supplies, and the like. Software routines, such as a method as described below may be stored in the memory 782 and, when executed by the CPU 780, transform the CPU 780 into a specific purpose computer (controller 778). The software routines may also be stored and/or executed by a second controller (not shown) that is located remotely from the process chamber 700.

The memory 782 is in the form of computer-readable storage media that contains instructions, when executed by the CPU 780, to facilitate the operation of the semiconductor processes and equipment. The instructions in the memory 782 are in the form of a program product such as a program that implements the methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

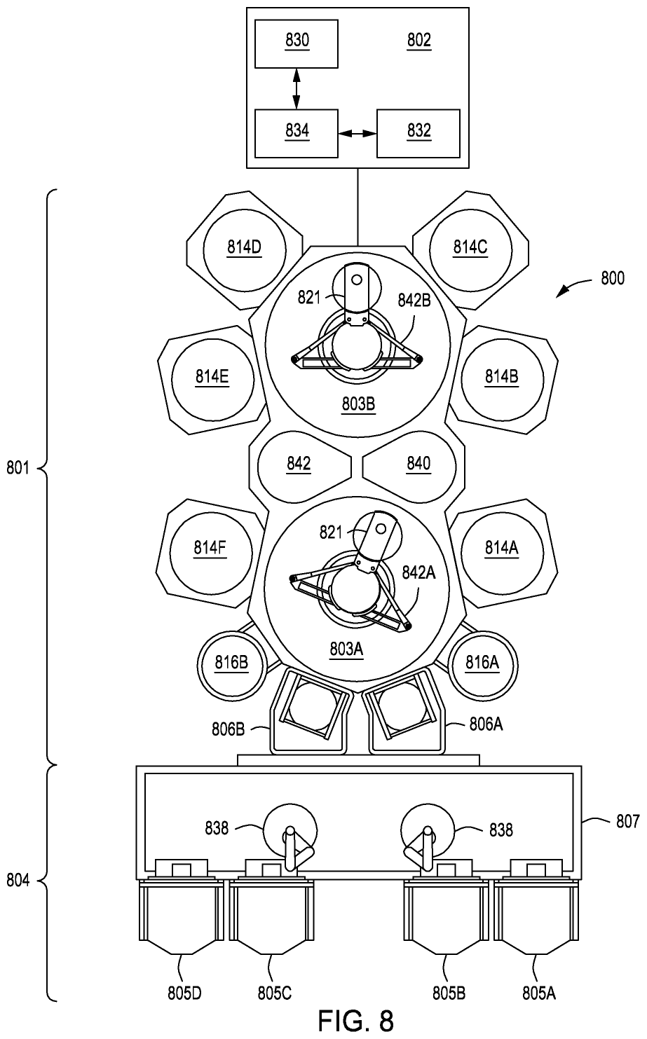

The methods described herein may be performed in individual process chambers that may be provided in a standalone configuration or as part of a cluster tool, for example, the integrated tool 800 (i.e., cluster tool) described below with respect to FIG. 8. The advantage of using an integrated tool 800 is that there is no vacuum break between chambers and, therefore, no requirement to degas and pre-clean a substrate before treatment in a chamber. For example, in some embodiments the inventive methods discussed above may advantageously be performed in an integrated tool such that there are limited or no vacuum breaks between processes, limiting or preventing contamination of the substrate such as oxidation and the like. The integrated tool 800 includes a vacuum-tight processing platform 801, a factory interface 804, and a system controller 802. The processing platform 801 comprises multiple processing chambers, such as 814A, 813B, 814C, 814D, 814E, and 814F operatively coupled to a vacuum substrate transfer chamber (transfer chambers 803A, 803B). The factory interface 804 is operatively coupled to the transfer chamber 803A by one or more load lock chambers (two load lock chambers, such as 806A and 806B shown in FIG. 8).

In some embodiments, the factory interface 804 comprises at least one docking station 807, at least one factory interface robot 838 to facilitate the transfer of the semiconductor substrates. The docking station 807 is configured to accept one or more front opening unified pod (FOUP). Four FOUPS, such as 805A, 805B, 805C, and 805D are shown in the embodiment of FIG. 8. The factory interface robot 838 is configured to transfer the substrates from the factory interface 804 to the processing platform 801 through the load lock chambers, such as 806A and 806B. Each of the load lock chambers 806A and 806B have a first port coupled to the factory interface 804 and a second port coupled to the transfer chamber 803A. The load lock chamber 806A and 806B are coupled to a pressure control system (not shown) which pumps down and vents the load lock chambers 806A and 806B to facilitate passing the substrates between the vacuum environment of the transfer chamber 803A and the substantially ambient (e.g., atmospheric) environment of the factory interface 804. The transfer chambers 803A, 803B have vacuum robots 842A, 842B disposed in the respective transfer chambers 803A, 803B. The vacuum robot 842A is capable of transferring substrates 821 between the load lock chamber 806A, 806B, the processing chambers 814A and 814F and a cooldown station 840 or a pre-clean station 842. The vacuum robot 842B is capable of transferring substrates 821 between the cooldown station 840 or pre-clean station 842 and the processing chambers 814B, 814C, 814D, and 814E.

In some embodiments, the processing chambers 814A, 814B, 814C, 814D, 814E, and 814F are coupled to the transfer chambers 803A, 803B. The processing chambers 814A, 814B, 814C, 814D, 814E, and 814F may comprise, for example, substrate soaking chambers, atomic layer deposition (ALD) process chambers, physical vapor deposition (PVD) process chambers, remote plasma chambers, chemical vapor deposition (CVD) chambers, annealing chambers, or the like. The chambers may include any chambers suitable to perform all or portions of the methods described herein, as discussed above, such as chlorine-based soaking chambers, remote plasma treatment chambers, and the like. In some embodiments, one or more optional service chambers (shown as 816A and 816B) may be coupled to the transfer chamber 803A. The service chambers 816A and 816B may be configured to perform other substrate processes, such as degassing, orientation, substrate metrology, cool down, and the like.

The system controller 802 controls the operation of the tool 800 using a direct control of the process chambers 814A, 814B, 814C, 814D, 814E, and 814F or alternatively, by controlling the computers (or controllers) associated with the process chambers 814A, 814B, 814C, 814D, 814E, and 814F and the tool 800. In operation, the system controller 802 enables data collection and feedback from the respective chambers and systems to optimize performance of the tool 800. The system controller 802 generally includes a Central Processing Unit (CPU) 830, a memory 834, and a support circuit 832. The CPU 830 may be any form of a general-purpose computer processor that can be used in an industrial setting. The support circuit 832 is conventionally coupled to the CPU 830 and may comprise a cache, clock circuits, input/output subsystems, power supplies, and the like. Software routines, such as a method as described above may be stored in the memory 834 and, when executed by the CPU 830, transform the CPU 830 into a specific purpose computer (system controller) 802. The software routines may also be stored and/or executed by a second controller (not shown) that is located remotely from the tool 800.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for cleaning a surface of a substrate, comprising:
performing a chlorine-based soak process to remove molybdenum oxide from the surface of the substrate in a back-end-of-the-line (BEOL) process, wherein the substrate contains, at least in part, low-k dielectric material; and
performing a plasma treatment on the surface of the substrate with a remote plasma containing a hydrogen gas diluted with at least one inert gas to remove residual chlorine residue from the surface of the substrate.

2. The method of claim 1, wherein the chlorine-based soak process uses molybdenum pentachloride (MoCl₅) or tungsten pentachloride (WCl₅).

3. The method of claim 1, further comprising:
performing the chlorine-based soak process at a temperature of approximately 350 degrees Celsius to approximately 460 degrees Celsius.

4. The method of claim 1, further comprising:
performing the chlorine-based soak process at a pressure of approximately 2 Torr to approximately 20 Torr.

5. The method of claim 1, further comprising:
performing the chlorine-based soak process with a chlorine-based gas flowing at a rate of approximately 10 sccm to approximately 1000 sccm.

6. The method of claim 1, further comprising:
performing the chlorine-based soak process for a duration of approximately 5 seconds to approximately 60 seconds.

7. The method of claim 1, wherein the at least one inert gas is argon gas or helium gas.

8. The method of claim 1, further comprising:
performing the plasma treatment at a temperature of approximately 250 degrees Celsius to approximately 460 degrees Celsius.

9. The method of claim 1, further comprising:
performing the plasma treatment at a pressure of approximately 10 mTorr to approximately 200 mTorr.

10. The method of claim 1, further comprising:
performing the plasma treatment with a plasma source power of approximately 400 watts to approximately 900 watts.

11. The method of claim 1, further comprising:
performing the plasma treatment with a bias power of zero watts to approximately 300 watts.

12. The method of claim 1, further comprising:
performing the plasma treatment with the hydrogen gas diluted down approximately 1% to approximately 99% by volume with the at least one inert gas.

13. The method of claim 1, further comprising:
performing the plasma treatment with the hydrogen gas flowing at a rate of approximately 1 sccm to approximately 100 sccm and the at least one inert gas flowing at a rate of approximately 5 sccm to approximately 200 sccm.

14. A method for cleaning a surface of a substrate, comprising:
performing a chlorine-based soak process using molybdenum pentachloride (MoCl₅) or tungsten pentachloride (WCl₅) to remove molybdenum oxide from the surface of the substrate in a back-end-of-the-line (BEOL) process at a temperature of approximately 350 degrees Celsius to approximately 460 degrees Celsius for a duration of approximately 5 seconds to approximately 60 seconds, wherein the substrate contains, at least in part, low-k dielectric material; and
performing a plasma treatment on the surface of the substrate with a remote plasma containing a hydrogen gas diluted with argon gas and helium gas at a temperature of approximately 250 degrees Celsius to approximately 460 degrees Celsius to remove residual chlorine residue from the surface of the substrate, wherein the hydrogen gas is diluted down approximately 3% to approximately 10% by volume with an argon gas and a helium gas.

15. The method of claim 14, further comprising:
performing the chlorine-based soak process at a pressure of approximately 2 Torr to approximately 20 Torr; or
performing the chlorine-based soak process with a chlorine-based gas flowing at a rate of approximately 10 sccm to approximately 1000 sccm.

16. The method of claim 14, further comprising:
performing the plasma treatment at a pressure of approximately 10 mTorr to approximately 200 mTorr.

17. The method of claim 14, further comprising:
performing the plasma treatment with the hydrogen gas flowing at a first rate of approximately 3 sccm to approximately 10 sccm, the argon gas flowing at a second rate of approximately 50 sccm to approximately 200 sccm, and the helium gas flowing at a third rate of approximately 50 sccm to approximately 200 sccm.

18. The method of claim 14, further comprising:
performing the plasma treatment with a plasma source power of approximately 400 watts to approximately 900 watts; or
performing the plasma treatment with a bias power of zero watts to approximately 300 watts.

19. A non-transitory, computer readable medium having instructions stored thereon that, when executed, cause a method for cleaning a surface of a substrate to be performed, the method comprising:
performing a chlorine-based soak process using molybdenum pentachloride (MoCl₅) or tungsten pentachloride (WCl₅) to remove molybdenum oxide from the surface of the substrate in a back-end-of-the-line (BEOL) process at a temperature of approximately 350 degrees Celsius to approximately 460 degrees Celsius for a duration of approximately 5 seconds to approximately 60 seconds, wherein the substrate contains, at least in part, low-k dielectric material; and
performing a plasma treatment on the surface of the substrate with a remote plasma containing a hydrogen gas diluted with argon gas and helium gas at a temperature of approximately 250 degrees Celsius to approximately 460 degrees Celsius to remove residual chlorine residue from the surface of the substrate, wherein the hydrogen gas is diluted down approximately 3% to approximately 10% by volume with an argon gas and a helium gas.

20. The non-transitory, computer readable medium of claim 19, further comprising:
performing the chlorine-based soak process at a pressure of approximately 2 Torr to approximately 20 Torr;
performing the chlorine-based soak process with a chlorine-based gas flowing at a rate of approximately 10 sccm to approximately 1000 sccm;
performing the plasma treatment at a pressure of approximately 10 mTorr to approximately 200 mTorr; or
performing the plasma treatment with the hydrogen gas flowing at a first rate of approximately 3 sccm to approximately 10 sccm, the argon gas flowing at a second rate of approximately 50 sccm to approximately 200 sccm, and the helium gas flowing at a third rate of approximately 50 sccm to approximately 200 sccm.
